(19) United States
(12) Patent Application Publication
(10) Pub. No.: US 2020/0362453 A1
(43) Pub. Date: Nov. 19, 2020

(54) METAL SURFACE PROTECTIVE LAYER AND PREPARATION METHOD THEREOF

(71) Applicant: CITIC Dicastal CO., LTD., Qinhuangdao (CN)

(72) Inventors: Shuai LI, Qinhuangdao (CN); Shengchao ZHANG, Qinhuangdao (CN)

(21) Appl. No.: 16/552,115

(22) Filed: Aug. 27, 2019

(30) Foreign Application Priority Data
May 17, 2019 (CN) 201910415163.9

(51) Int. Cl. C23C 14/35; C23C 14/16; C23C 14/02; C23C 24/08; C22C 19/05

(52) U.S. Cl. CPC C23C 14/352; C23C 14/16; C22C 19/05; C23C 14/028; C23C 24/087; C23C 14/024

(57) ABSTRACT

The present disclosure provides a metal surface protective layer and a preparation method thereof. The metal surface protective layer includes a base powder layer, a medium powder layer, a physical vapor deposition (PVD) metal coating and a transparent powder layer from inside to outside. The PVD metal coating is obtained by a magnetron vacuum sputtering method. The PVD metal coating at least includes a mixed coating adopting two targets: a Ni—Cr alloy and pure chromium.

### CROSS-REFERENCE TO RELATED APPLICATIONS

This application claims priority to Chinese Patent Application No. 201910415163.9, filed on May 17, 2019, the contents of which are hereby incorporated by reference in its entirety.

### BACKGROUND

An aluminum alloy wheel hub needs to be subjected to surface treatment after being machined, so as to form a surface protective layer, which makes the aluminum alloy wheel hub be higher in corrosion resistance and have a more beautiful appearance.

In the related art, surface treatment modes of the aluminum alloy wheel hub mainly include entire coating, fine turning, polishing and electroplating. A protective layer formed by electroplating is higher in corrosion resistance, higher in glossiness and more beautiful. However, an electroplating process is a very environmentally-unfriendly process mode since the electroplating needs to use a large amount of strong acid, strong alkali and heavy metal solution, and even harmful chemicals such as cyanide and chromic anhydride. These toxic and harmful substances may cause serious pollution to the local environment.

### SUMMARY

The present disclosure relates to metal surface treatment, and more particularly relates to a metal surface protective layer and a preparation method thereof.

The embodiments of the present disclosure provide a metal surface protective layer and a preparation method thereof, which can achieve the surface treatment effect of electroplating and is more environmentally friendly.

On the first aspect, the embodiments of the present disclosure provide a metal surface protective layer. The metal surface protective layer includes a base powder layer, a medium powder layer, a physical vapor deposition (PVD) metal coating and a transparent powder layer from inside to outside. The PVD metal coating is obtained by a magnetron vacuum sputtering method. The PVD metal coating at least includes a mixed coating adopting two targets: a Ni (Nickel)-Cr (Chromium) alloy and pure chromium.

In one embodiment, the PVD metal coating also includes an alloy coating with a Ni—Cr alloy serving as a target and a pure chromium coating with pure chromium serving as a target. The PVD metal coating is composed of the alloy coating, the mixed coating and the pure chromium coating in sequence from inside to outside.

In one embodiment, the material of the base powder layer is epoxy resin; the material of the medium powder layer is modified epoxy resin; and the material of the transparent powder layer is acrylic acid.

In one embodiment, the alloy coating, the mixed coating and the pure chromium coating are all 0.06 to 0.15 microns in thickness.

In one embodiment, the base powder layer, the medium powder layer and the transparent powder layer are all 80 to 120 microns in thickness.

On the second aspect, the embodiments of the present disclosure further provide a preparation method of the metal surface protective layer. The method includes the following steps:

spraying base powder to a surface to be treated to form a base powder layer;

spraying medium powder to the base powder layer to form a medium powder layer;

performing magnetron vacuum sputtering physical vapor deposition (PVD) coating on the medium powder layer to form a PVD metal coating; and spraying transparent powder to the PVD metal coating to form a transparent powder layer.

In one embodiment, the step of performing magnetron vacuum sputtering PVD coating on the medium powder layer to form a PVD metal coating includes:

coating the medium powder layer with a Ni—Cr alloy to form an alloy coating;

simultaneously coating the alloy coating with the Ni—Cr alloy and pure chromium to form a mixed coating; and

coating the mixed coating with the pure chromium to form a pure chromium coating.

In one embodiment, the step of performing magnetron vacuum sputtering PVD coating on the medium powder layer to form a PVD metal coating also includes that:

process parameters of the magnetron vacuum sputtering PVD coating are as follows: a coating temperature is 90 to 170° C., coating power is 0.6 to 1.2 kW, the vacuum degree is 2 to 0.006 Pa, inert gas used is argon, oxygen or nitrogen, the flow rate of the inert gas is 200 to 400 ml/min, and the coating time of both the alloy coating and the pure chromium coating is 5 to 8 s, and the coating time of the mixed coating is 18 to 24 s.

In one embodiment, before the step of spraying base powder to a surface to be treated to form a base powder layer, the method also includes:

performing primary pretreatment on the surface to be treated, and then grinding the surface to be treated;

before the step of spraying medium powder to the base powder layer to form a medium powder layer, the method also includes:

performing secondary pretreatment on the base powder layer; and

the primary pretreatment and the secondary pretreatment each include the following steps:

alkali washing, acid washing, passivation and sealing.

In one embodiment, the curing temperature of the base powder layer is 180° C., and the curing time is 20 min; the curing temperature of the medium powder layer is 210° C., and the curing time is 20 min; and the curing temperature of the transparent powder layer is 177° C., and the curing time is 17 min.

The embodiments of the present disclosure provide the metal surface protective layer and the preparation method thereof. The metal surface protective layer includes the base powder layer, the medium powder layer, the PVD metal coating and the transparent powder layer from inside to outside. The PVD metal coating is obtained by the magnetron vacuum sputtering method. The PVD metal coating at least includes a mixed coating adopting the two targets: the Ni (Nickel)-Cr (Chromium) alloy and the pure chromium. Therefore, the metal surface protective layer and the preparation method which are provided by the embodiments of the present disclosure can achieve the surface treatment effect of electroplating and is more environmentally friendly by adding the PVD coating into the metal surface protective layer.

Other beneficial effects of the embodiments of the present disclosure will be further described in conjunction with specific technical solutions in the specific embodiments.

### BRIEF DESCRIPTION OF THE DRAWINGS

FIG. 1 is a structural schematic diagram of a surface protective layer of an aluminum alloy wheel hub according to Example 1 of the present disclosure;

FIG. 2 is a structural schematic diagram of a physical vapor deposition (PVD) metal coating in a surface protective layer of an aluminum alloy wheel hub according to Example 1 of the present disclosure; and

FIG. 3 is flow diagram of a preparation method of a surface protective layer of an aluminum alloy wheel hub according to Example 2 of the present disclosure.

### DETAILED DESCRIPTION

The surface treatment of an aluminum alloy wheel hub also adopts a physical vapor deposition (PVD) coating process, but a PVD coating formed by the PVD coating process always has the problems of cracks and poor adhesion of transparent powder.

For the above problems, the embodiment of the present disclosure provides a metal surface protective layer. The metal surface protective layer is applied to both an aluminum alloy wheel hub and other automobile accessories, and can be further applied to elements of electronic equipment.

The metal surface protective layer includes a base powder layer, a medium powder layer, a PVD metal coating and a transparent powder layer from inside to outside. The PVD metal coating is obtained by a magnetron vacuum sputtering method. The PVD metal coating at least includes a mixed coating adopting two targets: a Ni—Cr alloy and pure chromium.

The metal surface protective layer provided by the embodiment of the present disclosure can achieve the surface treatment effect of electroplating and is more environmentally friendly by adding the PVD coating into the metal surface protective layer, and can also solve the problems of cracks and poor adhesion of transparent powder that the PVD coating always has.

In one embodiment, the PVD metal coating also includes an alloy coating with a Ni (Nickel)-Cr(Chromium) alloy serving as a target and a pure chromium coating with pure chromium serving as a target. The PVD metal coating is composed of the alloy coating, the mixed coating and the pure chromium coating in sequence from inside to outside. Here, the function of the alloy coating is to absorb internal stress generated by the thermal expansion and cold contraction of the pure chromium coating by utilization of the ductility. The function of the mixed coating is to well connect the alloy coating with the pure chromium coating. The function of the pure chromium coating is to realize high-brightness decoration and good combination with the transparent powder layer.

In one embodiment, the material of the base powder layer is epoxy resin. The material of the medium powder layer is modified epoxy resin. The material of the transparent powder layer is acrylic acid. The function of the base powder layer is to resist corrosion and realize initial appearance leveling. The function of the medium powder layer is to achieve a highly leveled surface for preparation for coating. Furthermore, the rigidity of the cured medium powder layer shall be greater than that of the base powder layer, which is advantageous for reducing the residual internal stress between the medium powder layer and the metal coating. The function of the transparent powder layer is to protect the metal coating.

In one embodiment, the alloy coating, the mixed coating and the pure chromium coating are all 0.06 to 0.15 microns in thickness. This thickness achieves relatively high production efficiency, and also may allow the surface of a part to meet a high-brightness appearance requirement.

In one embodiment, the base powder layer, the medium powder layer and the transparent powder layer are all 80 to 120 microns in thickness. This thickness may conform to a qualification test of a complete surface coating experiment for General Motors North America (GMNA).

The embodiment of the present disclosure further provides a preparation method of the above metal surface protective layer. The method includes the following steps:

spraying base powder to a surface to be treated to form a base powder layer;

spraying medium powder to the base powder layer to form a medium powder layer;

performing magnetron vacuum sputtering physical vapor deposition (PVD) coating on the medium powder layer to form a PVD metal coating; and

spraying transparent powder to the PVD metal coating to form a transparent powder layer.

In one embodiment, the step of performing magnetron vacuum sputtering PVD coating on the medium powder layer to form a PVD metal coating includes:

coating the medium powder layer with a Ni—Cr alloy to form an alloy coating;

simultaneously coating the alloy coating with the Ni—Cr alloy and pure chromium to form a mixed coating; and

coating the mixed coating with the pure chromium to form a pure chromium coating.

In one embodiment, the step of performing magnetron vacuum sputtering PVD coating on the medium powder layer to form a PVD metal coating also includes that:

process parameters of the magnetron vacuum sputtering PVD coating are as follows: a coating temperature is 90 to 170° C., coating power is 0.6 to 1.2 kW, the vacuum degree is 2 to 0.006 Pa, inert gas used is argon, oxygen or nitrogen, the flow rate of the inert gas is 200 to 400 ml/min, and the coating time of both the alloy coating and the pure chromium coating is 5 to 8 s, and the coating time of the mixed coating is 18 to 24 s. The adoption of these parameters may conform to the qualification test of the complete surface coating experiment for GMNA.

In one embodiment, before the step of spraying base powder to a surface to be treated to form a base powder layer, the method also includes:

performing primary pretreatment on the surface to be treated, and then grinding the surface to be treated;

before the step of spraying medium powder to the base powder layer to form a medium powder layer, the method also includes:

performing secondary pretreatment on the base powder layer; and

the primary pretreatment and the secondary pretreatment each include the following steps:

alkali washing, acid washing, passivation and sealing.

In one embodiment, the curing temperature of the base powder layer is 180° C., and the curing time is 20 min; the curing temperature of the medium powder layer is 210° C., and the curing time is 20 min; and the curing temperature of the transparent powder layer is 177° C., and the curing time is 17 min. In this way, all the layers are firmly cured, and may exert corresponding functions.

Detailed technical solutions of the present disclosure will be described below in combination with accompanying drawings and specific Examples. It should be understood that the attached drawings and the Examples are merely explanatory of the present disclosure, but not intended to limit the present disclosure.

### EXAMPLE 1

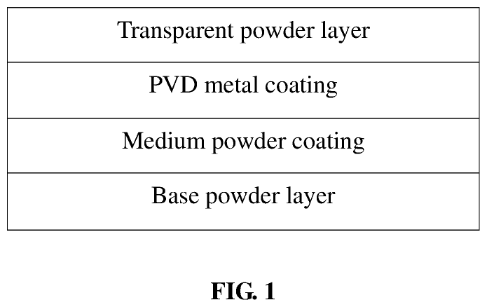

The present Example provides a surface protective layer of an aluminum alloy wheel hub. As shown in FIG. 1, the surface protective layer includes a base powder layer, a medium powder layer, a PVD metal coating and a transparent powder layer from inside to outside, namely from bottom to top in the figure.

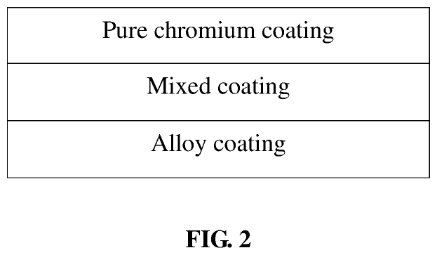

The PVD metal coating is obtained by a magnetron vacuum sputtering method. As shown in FIG. 2, the PVD metal coating is composed of an alloy coating, a mixed coating and a pure chromium layer in sequence from inside to outside. A Ni—Cr alloy is the target of the alloy coating. The Ni—Cr alloy and pure chromium are the targets of the mixed coating. The pure chromium is the target of the pure chromium coating. Specifically, the Ni—Cr alloy contains 75% of nickel and 25% of chromium. The purity of the pure chromium is 99.95%.

The material of the base powder layer is epoxy resin; the material of the medium powder layer is modified epoxy resin; and the material of the transparent powder layer is acrylic acid.

The alloy coating, the mixed coating and the pure chromium coating are all 0.06 micron in thickness.

The base powder layer, the medium powder layer and the transparent powder layer are all 80 microns in thickness.

### EXAMPLE 2

In the present Example, except that the thicknesses of the alloy coating, the mixed coating and the pure chromium coating and the thicknesses of the base powder layer, the medium powder layer and the transparent powder layer are different from Example 1, other contents are all the same as those in Example 1. The contents different from the above contents are described below.

In the present Example, the alloy coating, the mixed coating and the pure chromium coating are all 0.15 microns in thickness.

In the present Example, the base powder layer, the medium powder layer and the transparent powder layer are all 120 microns in thickness.

### EXAMPLE 3

In the present Example, except that the thicknesses of the alloy coating, the mixed coating and the pure chromium coating and the thicknesses of the base powder layer, the medium powder layer and the transparent powder layer are different from Example 1, other contents are all the same as those in Example 1. The contents different from the above contents are described below.

In the present Example, the alloy coating, the mixed coating and the pure chromium coating are all 0.15 microns in thickness.

In the present Example, the base powder layer, the medium powder layer and the transparent powder layer are all 80 microns in thickness.

### EXAMPLE 4

In the present Example, except that the thicknesses of the alloy coating, the mixed coating and the pure chromium coating and the thicknesses of the base powder layer, the medium powder layer and the transparent powder layer are different from Example 1, other contents are all the same as those in Example 1. The contents different from the above contents are described below.

In the present Example, the alloy coating, the mixed coating and the pure chromium coating are all 0.06 micron in thickness.

In the present Example, the base powder layer, the medium powder layer and the transparent powder layer are all 120 microns in thickness.

### EXAMPLE 5

In the present Example, except that the thicknesses of the alloy coating, the mixed coating and the pure chromium coating and the thicknesses of the base powder layer, the medium powder layer and the transparent powder layer are different from Example 1, other contents are all the same as those in Example 1. The contents different from the above contents are described below.

The alloy coating, the mixed coating and the pure chromium coating are all 0.1 micron in thickness.

The base powder layer, the medium powder layer and the transparent powder layer are all 100 microns in thickness.

### EXAMPLE 6

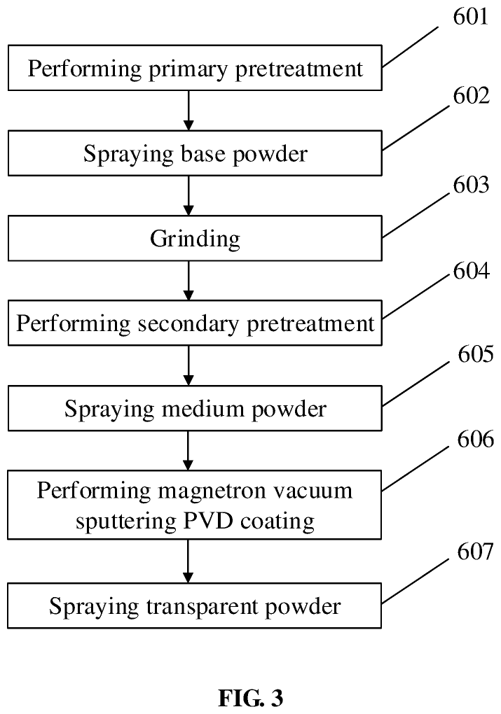

The present Example provides a preparation method of a surface protective layer of an aluminum alloy wheel hub. As shown in FIG. 3, the preparation method includes the following steps that:

Step 601: primary pretreatment. The primary pretreatment is performed on a surface to be treated, namely a semifinished surface of the aluminum alloy wheel hub. The primary pretreatment includes the following steps: water washing, alkali washing, water washing, acid washing, pure water washing, passivation, sealing, water washing and drying.

Step 602: spraying of base powder. The base powder is sprayed to the surface to be treated subjected to the primary pretreatment to form a base powder layer. Specifically, the curing temperature of the base powder layer is 180° C., and the curing time is 20 min.

Step 603: grinding. The surface of the base powder layer is finely ground. Specifically, the surface is ground with 800/1000-mesh abrasive paper.

Step 604: secondary pretreatment. Secondary pretreatment is performed on the ground surface to be treated. The secondary pretreatment includes the following steps: water washing, alkali washing, water washing, acid washing, pure water washing, passivation, sealing, water washing and drying.

Step 605: spraying of medium powder. The medium powder is sprayed to the surface to be treated subjected to the secondary pretreatment to form a medium powder layer. Specifically, the curing temperature of the medium powder layer is 210° C., and the curing time is 20 min.

Step 606: magnetron vacuum sputtering PVD coating. The magnetron vacuum sputtering PVD coating is performed on the surface of the medium powder layer to form a PVD metal coating. The PVD metal coating includes an alloy coating, a mixed coating and a pure chromium layer in sequence from inside to outside. A Ni—Cr alloy is the target of the alloy coating. The Ni—Cr alloy and pure chromium are the targets of the mixed coating. The pure chromium is the target of the pure chromium coating. Specifically, process parameters of the magnetron vacuum sputtering PVD coating are as follows: a coating temperature is 90° C., coating power is 0.6 kW, the vacuum degree is 0.006 Pa, inert gas used is argon, the flow rate of the inert gas is 200 ml/min, and the coating time of the alloy coating is 8 s, the coating time of the mixed coating is 18 s, and the coating time of the pure chromium coating is 8 s.

Further, when nitrogen or oxygen is used as the inert gas, a unique coating appearance color may be formed on the surface of the aluminum alloy wheel hub, and never appears in the magnetron vacuum sputtering PVD coating before.

Step 607: spraying of transparent powder. The transparent powder is sprayed to the PVD metal coating to form a transparent powder layer. Specifically, the curing temperature of the transparent powder layer is 177° C., and the curing time is 17 min. After the transparent powder layer is cured, the whole surface treatment process is completed.

Specifically, equipment adopted in the preparation method is a continuous PVD coating machine.

### EXAMPLE 7

Except that the coating temperature of the magnetron vacuum sputtering PVD coating is different from that in Example 1, other contents of the technological process of the present Example are all the same as those in Example 1. The contents different from the above contents are described below, and will be no longer shown in the flow diagram separately.

In the present Example, the coating temperature is 170° C.

### EXAMPLE 8

Except that the coating power of the magnetron vacuum sputtering PVD coating is different from that in Example 1, other contents of the technological process of the present Example are all the same as those in Example 1. The contents different from the above contents are described below, and will be no longer shown in the flow diagram separately.

In the present Example, the coating power is 1.2 kW.

### EXAMPLE 9

Except that the coating temperature and the coating power of the magnetron vacuum sputtering PVD coating are different from those in Example 1, other contents of the technological process of the present Example are all the same as those in Example 1. The contents different from the above contents are described below, and will be no longer shown in the flow diagram separately.

In the present Example, the coating temperature is 170° C., and the coating power is 1.2 kW.

### EXAMPLE 10

Except that the coating time of the magnetron vacuum sputtering PVD coating is different from that in Example 1, other contents of the technological process of the present Example are all the same as those in Example 1. The contents different from the above contents are described below, and will be no longer shown in the flow diagram separately.

In the present Example, the coating time of the alloy coating is 5 s, the coating time of the mixed coating is 24 s, and the coating time of the pure chromium coating is 5 s.

### EXAMPLE 11

Except that the coating temperature and the coating time of the magnetron vacuum sputtering PVD coating are different from those in Example 1, other contents of the technological process of the present Example are all the same as those in Example 1. The contents different from the above contents are described below, and will be no longer shown in the flow diagram separately.

In the present Example, the coating temperature is 170° C., the coating time of the alloy coating is 5 s, the coating time of the mixed coating is 24 s, and the coating time of the pure chromium coating is 5 s.

### EXAMPLE 12

Except that the coating power and the coating time of the magnetron vacuum sputtering PVD coating are different from those in Example 1, other contents of the technological process of the present Example are all the same as those in Example 1. The contents different from the above contents are described below, and will be no longer shown in the flow diagram separately.

In the present Example, the coating power is 1.2 kW, the coating time of the alloy coating is 5 s, the coating time of the mixed coating is 24 s, and the coating time of the pure chromium coating is 5 s.

### EXAMPLE 13

Except that the coating temperature, the coating power and the coating time of the magnetron vacuum sputtering PVD coating are different from those in Example 1, other contents of the technological process of the present Example are all the same as those in Example 1. The contents different from the above contents are described below, and will be no longer shown in the flow diagram separately.

In the present Example, the coating temperature is 170° C., the coating power is 1.2 kW, the coating time of the alloy coating is 5 s, the coating time of the mixed coating is 24 s, and the coating time of the pure chromium coating is 5 s.

In order to compare with a surface treatment technology in the related art, two comparative examples are particularly taken.

### COMPARATIVE EXAMPLE 1

The target used is a pure chromium single target. The preparation method used is the same as the preparation method of the pure chromium coating of the present disclosure.

### COMPARATIVE EXAMPLE 2

The target used is a Ni—Cr alloy single target, and the preparation method used is the same as the preparation method of the alloy coating of the present disclosure.

The above Comparative Examples and the specific Examples of the present disclosure are subjected to test comparison. Detailed test items and data are as follows:

(1) surface crack test: 5 samples are randomly extracted from an obtained metal surface, and each sample is a square having an edge length of 1 cm; furthermore, a crack length in each rectangle is calculated; therefore, a crack density of the surface is obtained; and the surface crack densities of the respective comparative examples and Examples are as shown in Table 1;

TABLE 1

| Comparative Examples or Examples | Surface crack density (cm/cm²) |
|---|---|
| Comparative Example 1 | 4 |
| Comparative Example 2 | No crack |
| Example 1 | No crack |
| Example 2 | No crack |
| Example 3 | No crack |
| Example 4 | No crack |
| Example 5 | No crack |

(2) thermal shock test: the following steps are performed according to an order: water immersion (at a temperature of 38+/−2° C.) ×3 h, freezing (at a temperature of −29+/−3° C.)×3 h, scribing (scribing X at an angle of 60 degrees), and shock by high-pressure water vapor at 100° C. (a distance of 5 to 7.5 cm, a jet angle of 45 degrees, and a duration of 30 s); and test results are as shown in Table 2;

TABLE 2

| Comparative Examples or Examples | Surface crack density (cm/cm²) |
|---|---|
| Comparative Example 1 | No falling |
| Comparative Example 2 | Transparent powder layer falls off |
| Example 1 | No falling |
| Example 2 | No falling |
| Example 3 | No falling |
| Example 4 | No falling |
| Example 5 | No falling |

(3) Copper-Accelerated Acetic Acid Salt Spray (CASS) test: the test is performed in accordance with CASS Test Standard Method, NO. 01, 1975, of Corrosion Resistance News, and test results are as shown in Table 3.

TABLE 3

| Comparative Examples or Examples | Surface crack density (cm/cm²) |
|---|---|
| Comparative Example 1 | Ok |
| Comparative Example 2 | Transparent powder layer falls off |
| Example 1 | Ok |
| Example 2 | Ok |
| Example 3 | Ok |
| Example 4 | Ok |
| Example 5 | Ok |

The above contents are only specific descriptions of the Examples of the present disclosure, and not intended to limit the protection scope of the present disclosure. Any other equivalent transformations shall all fall within the protection scope of the present disclosure.

1. A metal surface protective layer, comprising a base powder layer, a medium powder layer, a physical vapor deposition (PVD) metal coating and a transparent powder layer from inside to outside,
wherein the PVD metal coating is obtained by a magnetron vacuum sputtering method; and
the PVD metal coating at least comprises a mixed coating adopting two targets: a Ni—Cr alloy and pure chromium.

2. The metal surface protective layer according to claim 1, wherein the PVD metal coating further comprises an alloy coating with a Ni—Cr alloy serving as a target and a pure chromium coating with pure chromium serving as a target; and
the PVD metal coating is composed of the alloy coating, the mixed coating and the pure chromium coating in sequence from inside to outside.

3. The metal surface protective layer according to claim 2, wherein a material of the base powder layer is an epoxy resin;
a material of the medium powder layer is a modified epoxy resin; and
a material of the transparent powder layer is acrylic acid.

4. The metal surface protective layer according to claim 2, wherein the alloy coating, the mixed coating and the pure chromium coating are all 0.06 to 0.15 microns in thickness.

5. The metal surface protective layer according to claim 2, wherein the base powder layer, the medium powder layer and the transparent powder layer are all 80 to 120 microns in thickness.

6. A preparation method of the metal surface protective layer according to claim 1, comprising:
spraying base powder to a surface to be treated to form a base powder layer;
spraying medium powder to the base powder layer to form a medium powder layer;
performing magnetron vacuum sputtering physical vapor deposition (PVD) coating on the medium powder layer to form a PVD metal coating; and
spraying transparent powder to the PVD metal coating to form a transparent powder layer.

7. The method according to claim 6, wherein the step of performing magnetron vacuum sputtering PVD coating on the medium powder layer to form a PVD metal coating comprises:
coating the medium powder layer with a Ni—Cr alloy to form an alloy coating;
simultaneously coating the alloy coating with the Ni—Cr alloy and pure chromium to form a mixed coating; and
coating the mixed coating with the pure chromium to form a pure chromium coating.

8. The method according to claim 7, wherein in the step of performing magnetron vacuum sputtering PVD coating on the medium powder layer to form a PVD metal coating, process parameters of the magnetron vacuum sputtering PVD coating are as follows: a coating temperature is 90 to 170° C., a coating power is 0.6 to 1.2 kW, a vacuum degree is 2 to 0.006 Pa, an inert gas used is argon, oxygen or nitrogen, a flow rate of the inert gas is 200 to 400 ml/min, and a coating time of both the alloy coating and the pure chromium coating is 5 to 8 s, and a coating time of the mixed coating is 18 to 24 s.

9. The method according to claim 6, wherein before the step of spraying base powder to a surface to be treated to form a base powder layer, the method further comprises:
performing primary pretreatment on the surface to be treated, and then grinding the surface to be treated;
before the step of spraying medium powder to the base powder layer to form a medium powder layer, the method further comprises:
performing secondary pretreatment on the base powder layer;
the primary pretreatment and the secondary pretreatment each comprise:
alkali washing, acid washing, passivation and sealing.

10. The method according to claim 6, wherein a curing temperature of the base powder layer is 180° C., and a curing time of the base powder layer is 20 min; a curing temperature of the medium powder layer is 210° C., and a curing time of the medium powder layer is 20 min; and a curing temperature of the transparent powder layer is 177° C., and a curing time of the transparent powder layer is 17 min.
